(19) United States
(12) Patent Application Publication
(10) Pub. No.: US 2007/0095366 A1
(43) Pub. Date: May 3, 2007

(54) Stripping and cleaning of organic-containing materials from electronic device substrate surfaces

(75) Inventor: Steven Verhaverbeke, San Francisco, CA (US)

Correspondence Address: SHIRLEY L. CHURCH, ESQ., P.O. BOX 81146, SAN DIEGO, CA, 92138, US

(73) Assignee: Applied Materials, Inc.

(21) Appl. No.: 11/588,093

(22) Filed: Oct. 25, 2006

Related U.S. Application Data
(60) Provisional application No. 60/732,793, filed on Nov. 2, 2005.

(51) Int. Cl. B08B 3/00; C23G 1/00; C23D 17/00

(52) U.S. Cl. 134/26; 134/38; 134/2

(57) ABSTRACT

Disclosed herein is a method of removing an organic material from an electronic device substrate surface. The method is particularly useful when the device substrate includes exposed metal. According to the present method, an electronic device substrate surface is exposed to a solution comprising ozone (O₃) at a concentration ranging from about 45 ppm to about 600 ppm in a solvent consisting of pure propionic acid or propionic acid in combination with deionized water or a carbonate having from 2 to 4 carbons. The method is particularly useful in the manufacture of large surface areas covered with device structures, such as electronic TFT flat panel displays, solar cell arrays, and structures containing light-emitting diodes. The method is also useful for removing organic materials from the surface of solid state device-containing semiconductor substrates.

### BACKGROUND OF THE INVENTION

1. Field of the Invention

The invention relates to a method of removing organic-containing materials such as photoresists, high temperature organic layers, and organic dielectric materials from an electronic device substrate surface. The method is particularly useful in the manufacture of large surface areas covered with device structures, such as electronic TFT flat panel displays, solar cell arrays, structures containing light-emitting diodes, and semiconductor wafers.

2. Brief Description of the Background Art

The fabrication of electronic device structures is complicated by the number of different materials which are used, both to provide the elements of the functional device, and as temporary process structures during fabrication of the device. Since most of the devices involve the formation of layers of inter-related, intricate, patterned structures, photoresists and high temperature organic masking materials are commonly used during patterning of underlying layers of material which are present over large area (1 m² or greater) surfaces. A patterned photoresist is one of the temporary processing structures and must be removed once work on the underlying structure through openings in the photoresist is completed. Therefore, there is a need for an efficient and inexpensive method of removing, stripping, or cleaning of organic photoresists, as well as other organic layer residues, from substrate surfaces. Due to the varying composition of a substrate underlying a photoresist, for example, it is important that a method used to remove the photoresist not be reactive with (corrosive to) surfaces underlying the photoresist. One problem has been the presence of metallic materials and the tendency of these materials to oxidize.

To be useful in processing of large surface areas, it is helpful to have the stripping and cleaning material be a non-corrosive fluid. The fluid should be minimally affected by the presence of an ambient atmospheric condition. It is also helpful when the removal process can be carried out at room temperature, or at least below about 50° C. Finally, it is always desirable that the fluid used for removal of the organic material be environmentally friendly.

In order to remove an organic material such as a photoresist for example, and specifically to strip photoresist from large substrate surfaces, a number of techniques have been used. Representative techniques for removing photoresists, as well as their advantages and disadvantages, are described below.

A Piranha solution, which consists of sulfuric acid (H₂SO₄) and hydrogen peroxide (H₂O₂), typically in a volumetric ratio of 4:1, works well for photoresist removal, but cannot be used on substrate surfaces which include exposed metal, because it will etch the metal. Also, because it is very viscous, the Piranha solution is difficult to rinse off a substrate surface after a photoresist removal process. Further, the H₂SO₄/H₂O₂ solution cannot be recovered or re-used many times, as it decomposes rapidly. Finally, the solution needs to be applied at relatively high temperatures of at least 70° C., and typically about 120° C.

Several other techniques for removal of organic photoresists are based on the use of organic solvent-based strippers, such as monoethanolamine (MEA), dimethylsulfoxide (DMSO), n-methylpyrrolidone (NMP), propylene glycol monomethyl ether acetate (PGMEA), ethyl lactate, and methylethylketone (MEK). Unlike the Piranha solution, these organic solvent strippers can be used when metals are present. However, these organic solvent strippers cannot be easily recovered after saturation with dissolved photoresist, because the photoresist is difficult to separate from the organic solvent. Therefore, the saturated organic solvent strippers must be disposed of frequently, creating an environmental problem. Like the Piranha solution, these solvents are typically heated prior to use, but to somewhat lower temperatures than the Piranha solution, typically around 50-65° C.

Japanese Patent Publication No. 59125760, of Tanno et al., published Jan. 10, 1986, describes dissolving ozone in an organic acid (such as formic acid or acetic acid) and using the ozonated organic acid to remove contamination from semiconductor substrates. Any heavy metal on the wafer is said to form a formate or an acetate, and any organic contaminant is decomposed by ozone, so that stains on the surface of the substrate can be removed.

T. Ohmi et al., in an article entitled “Native Oxide Growth and Organic Impurity Removal on Si Surface with Ozone-Injected Ultrapure Water” (J. Electrochem. Soc., Vol. 140, No. 3, March 1993), describe the use of ozone-injected ultrapure water to remove adsorbed organic impurities from a wafer surface prior to other wafer cleaning procedures. Ozone concentration in the water was 1-2 ppm. The process described by Ohmi et al. was said to be capable of effectively removing organic contaminants from the wafer surface in a short time at room temperature. Processing waste from the process was said to be simple, and the chemical composition of the ozone-injected ultrapure water was said to be easily controllable.

U.S. Pat. No. 5,464,480, issued Nov. 7, 1995, to Matthews et al., and entitled “Process and Apparatus for the Treatment of Semiconductor Wafers in a Fluid”, describes a process for removing organic materials from semiconductor wafers using chilled deionized water (1° C.-15° C.). The amount of ozone dissolved in the water is temperature-dependent. Lowering the temperature of the water is said to have increased the concentration of ozone in the water and to have increased the photoresist strip rate using the ozone/chilled water solution.

U.S. Pat. No. 5,632,847, issued May 27, 1997, to Ohno et al., and entitled “Film Removing Method and Film Removing Agent”, describes a method of removing a film (e.g., an organic or metal-contaminated film) from a substrate surface by injecting ozone into an inorganic acid aqueous solution (e.g., a mixed solution of dilute HF and dilute HCl) and bringing bubbles formed by the ozone injection into direct contact with the film. Each bubble is said to be composed of an inside ozone bubble and an outside acid aqueous solution bubble. The Ohno et al. reference recommends an acid aqueous solution of 5 weight % or less, kept at room temperature, where the ozone concentration is within a range from 40,000 ppm to 90,000 ppm. Ozone has also been dissolved in sulfuric acid for use in cleaning semiconductor surfaces, as described, for example, in U.S. Pat. Nos. 4,917,123 and 5,082,518.

U.S. Pat. No. 5,690,747, issued Nov. 25, 1997, to Doscher, and entitled “Method for Removing Photoresist with Solvent and Ultrasonic Agitation”, describes a method for removing photoresist using liquid organic solvents which include at least one polar compound having at least one strongly electronegative oxygen (such as ethylene diacetate) and at least one alicyclic carbonate (such as ethylene carbonate).

European Patent Publication No. 0867924, of Stefan DeGendt et al., published Sep. 30, 1998, and entitled “Method for Removing Organic Contaminants from a Substrate”, describes the use of an agent to remove the organic contaminants, where the agent comprises water vapor, ozone, and an additive acting as a scavenger. Use of a liquid agent comprising water, ozone, and an additive acting as a scavenger is also discussed. The additive is recommended to be an OH radical scavenger, such as a carboxylic or phosphoric acid or a salt thereof. Preferred examples are acetic acid and acetate, as well as carbonate and phosphate. Although carboxylic acids as a whole are mentioned, there is no data for any carboxylic acid other than acetic acid. The authors describe how the ozone level of an aqueous ozone solution increases upon the addition of acetic acid to the water-based solution. They also disclose that photoresist strip rate increases upon the addition of acetic acid to an aqueous ozone solution. This publication is incorporated by reference in its entirety.

U.S. Pat. No. 6,080,531, issued Jun. 27, 2000, to Carter et al., and entitled “Organic Removal Process” describes a method of photoresist removal in which a treating solution of ozone and bicarbonate (or other suitable radical scavenger) is used to treat a substrate for use in an electronic device. The concentration of bicarbonate ion or carbonate ion in the treating solution is said to be approximately equal to or greater than the ozone concentration. The method is said to be suited to removal of photoresist (as well as other organic materials) where metals such as aluminum, copper, and their oxides are present on the substrate surface.

Japanese Patent Publication No. 2002/025971, published Jan. 25, 2002, and assigned to Seiko Epson Corp. and Sumitomo Precision Prod. Co., teaches the use of ozonated water with acetic acid and ultraviolet radiation to remove photoresist. Ozonated water containing acetic acid is continuously supplied to the center portion of a rotating substrate. The ultraviolet rays from a UV lamp are irradiated onto the substrate to remove resist adhering to the surface of the substrate. The process is said to remove organic substances such as resist adhering onto the substrate without need for high temperature heat treatment.

U.S. Patent Application Publication No. 2002/0066717 A1, of Verhaverbeke et al., published Jun. 6, 2002, and entitled “Apparatus for Providing Ozonated Process Fluid and Methods for Using Same”, describes apparatus and methods for wet processing of electronic components using ozonated process fluids. Verhaverbeke et al. teach that it is desirable to have as high an ozone concentration as possible to achieve rapid cleaning of electronic components. Verhaverbeke et al. achieved ozone concentrations in water up to 300 g/m³ by using a closed vessel with recirculated ozonated liquid, which is supplied under pressure. Verhaverbeke et al. describe the use of various chemically reactive process fluids which may be used in combination with ozone, including inorganic acids, inorganic bases, fluorinated compounds, and acetic acid. The Verhaverbeke et al. reference also provides an overview of the literature on the use of ozonated deionized water for photoresist removal from electronic component surfaces. This published patent application is incorporated by reference in its entirety.

U.S. Patent Publication No. 2002/0173156 A1, of Yates et al., published Nov. 21, 2002, and entitled “Removal of Organic Material in Integrated Circuit Fabrication Using Ozonated Organic Acid Solutions”, describes the use of organic acid components to increase the solubility of ozone in aqueous solutions which are used for removing organic materials, such as polymeric resist or post-etch residues, from the surface of an integrated circuit device during fabrication. Each organic acid component is preferably said to be chosen for its metal-passivating effect. Such solutions are said to have significantly lower corrosion rates when compared to ozonated aqueous solutions using common inorganic acids for ozone solubility enhancement, due to a surface passivating effect of the organic acid component.

U.S. Pat. No. 6,551,409, issued Apr. 22, 2003, to DeGendt et al., and entitled “Method of Removing Organic Contaminants from a Semiconductor Surface”, describes a method for removing organic contaminants from a semiconductor surface, where the semiconductor is held in a tank which is filled with a gas mixture comprising water vapor and ozone. DeGendt et al. teach that the use of gas phase processing, where the substrate surface is contacted with an ozone/water vapor mixture, enables an increase in ozone concentration near the wafer surface.

U.S. Pat. No. 6,674,054, issued Jan. 6, 2004, to Boyers et al., and entitled “Method and Apparatus for Heating a Gas-Solvent Solution”, describes a method of quickly heating a gas-solvent solution from a relatively low temperature T₁ to a relatively high temperature T₂, such that the dissolved gas concentration at T₂ is much higher than if the gas had originally been dissolved into the solvent at T₂. The example of gas-solvent solution is an ozone gas in water solution. The objective is to heat a cold ozone-water solution using an in-line heater just prior to application of the solution to a substrate surface, to increase the reaction rate at the substrate surface. Table A in Col. 33 shows the solubility of ozone gas in water as a function of temperature and pressure. This '054 patent is incorporated by reference in its entirety.

U.S. Pat. No. 6,696,228, issued Feb. 4, 2004, to Muraoka et al., and entitled “Method and Apparatus for Removing Organic Films”, describes a method and apparatus for removing an organic film such as a resist film from a substrate surface using a treatment liquid which can be recycled and re-used. The treatment liquid is typically formed from liquid ethylene carbonate, liquid propylene carbonate, or a mixture thereof, and typically contains dissolved ozone. Since ethylene carbonate is a solid at room temperature, this photoresist removal method requires the use of elevated temperatures, in the range of about 50-120° C.

U.S. Pat. No. 6,699,330, issued Mar. 2, 2004, to Muraoka, and entitled “Method of Removing Contamination Adhered to Surfaces and Apparatus Used Therefor”, describes a method of removing surface-deposited contaminants from substrates for electronic devices. The method includes bringing an ozone-containing treating solution into contact with the surface of a treating target (such as a semiconductor substrate) on which contaminants have deposited. The ozone-containing treating solution comprises an organic solvent having a partition coefficient to ozone of 0.6 or more, where the partition coefficient refers to a partition coefficient of gaseous ozone between the organic solvent that is in a liquid phase in a standard condition and an inert gas in a gaseous phase which comes in contact with the organic solvent. Any organic solvents are said to be useful in the invention, so long as they provide the desired partition coefficient. Preferably organic solvents are fatty acids, including acetic acid, propionic acid, and butyric acid, with enabling embodiments provided for acetic acid. The author particularly prefers using acetic acid as the organic solvent, due to the price, commercial availability for high-purity products, and relative non-toxicity of acetic acid. The ozonated acetic acid is used in a closed system with a constant ozone partial pressure above the system to keep a high concentration of ozone in the acetic acid and to minimize evaporation of the acetic acid.

Although high concentrations (≧200 ppm) of ozone can be obtained in acetic acid, and ozonated acetic acid may provide a rapid photoresist strip rate (≧1 μm/min), there are major drawbacks to the use of ozonated acetic acid for photoresist removal. One of the primary considerations is corrosivity. Acetic acid has a conductivity of 1.12×10⁻⁸ mho/cm at 25° C. At 18° C., the conductivity of acetic acid is even higher (5×10⁻⁷ mho/cm). This is too high, and causes corrosion of metals, in particular, copper and molybdenum. These metals are commonly used in the semiconductor and flat panel display industries. Therefore, ozonated acetic acid should only be used on substrates which have no metals present.

Acetic acid is a solid at temperatures below about 16.7° C., which can cause problems under some desired processing conditions. In addition, although relatively non-toxic, acetic acid has a very strong, pungent odor. Even if there is a very small leak in a closed system containing acetic acid, an unpleasant working environment will be created for operators and other employees working in that environment.

Therefore, there is a need for a method of stripping and cleaning organic materials from electronic device surfaces, which method can be used when metals are present. In particular, there is a need for such a stripping and cleaning method which has universal applicability with respect to the surface composition of the substrate. Due to the common presence of metals in semiconductor device substrates, flat panel display substrates, and solar cell arrays, methods of stripping and cleaning organic materials which are harmful when metals are present are not attractive.

Further, there is a need for a stripping and cleaning solution that can be applied in a spray mode on a stationary object or on an object that is propagating on a conveyor belt in an open (exhausted) environment. This is particularly necessary in the manufacture of large flat panel substrates (such as those used for LCD or LED panels) and solar panels.

It would be highly desirable if the stripping and cleaning solution could be re-used over multiple processing cycles, without the need for frequent replenishment or filtering of the solution. It would also be advantageous if such an improved photoresist removal method could be performed at room temperature.

### SUMMARY OF THE INVENTION

Applicant has developed an improved method of removing an organic-containing material from the surface of an electronic device substrate. Applicants' method has the following advantages: The method provides a high organic material removal rate of at least 0.5 μm/min . The reagent solution used for removing an organic-containing material (“stripping solution”) avoids reactivity with metals to any extent which affects the overall electronic performance of the metal. The organic-containing material removal process can be performed at temperatures ranging from about 15° C. to about 50° C., taking into consideration the flash point of the reagent solution. The organic material removal process may be performed in an open, exhausted system, if desired. The stripping solution can be recycled over multiple processing cycles.

Applicants' organic material removal method comprises exposing a surface of an electronic device substrate to a solution comprising ozone (O₃) in a solvent, where the solvent is non-reactive with ozone and exhibits a volatility which is no more than 30% higher than, and no more than 50% lower than, the volatility of propionic acid. The solvent may be pure propionic acid, or may be propionic acid in combination with an ingredient selected from the group consisting of deionized water or a carbonate having from 2 to 4 carbons.

In an embodiment of the method which can be used when the substrate surface includes exposed metal, the substrate surface is exposed to a solution comprising ozone (O₃) in a solvent, where the solvent is pure propionic acid or propionic acid in combination with deionized water or with a carbonate having from 2 to 4 carbons.

The concentration of ozone in the solution typically ranges from about 50 ppm to about 600 ppm; preferably, from about 100 ppm to about 500 ppm; more preferably, from about 300 ppm to about 450 ppm. When the solvent is pure propionic acid, the concentration of ozone in the solution typically ranges from about 200 ppm to about 600 ppm. If the stripping solution contains too little ozone, the organic material removal rate will be unacceptably slow. If the stripping solution contains too much ozone, the corrosion rate of metals present on the substrate surface may be too high. With minimal experimentation, one skilled in the art will be able to determine an appropriate ozone concentration, based on the type of metal(s) which is (are) present on the substrate surface. When the substrate surface includes exposed metal, the ozone concentration in the stripping solution preferably ranges from about 75 ppm to about 45 ppm. When the exposed metal includes copper, the ozone concentration in the stripping solution is preferably in the range of about 50 ppm or less. Because the solubility of ozone in propionic acid increases as the concentration of propionic acid increases, which increases the organic material removal rate, the preferred concentration of propionic acid in the stripping/cleaning solvent should be as high as possible, depending on the substrate beneath the organic material.

When the solvent comprises propionic acid in combination with about 10 to about 20 volume % deionized water, the concentration of ozone in a stripping solution typically ranges from about 50 ppm to about 300 ppm. When the solvent comprises propionic acid in combination with about 40 to about 60 volume % ethylene carbonate, the concentration of ozone in the solution typically ranges from about 100 ppm to about 50 ppm, and more typically from about 75 ppm to about 45 ppm, respectively. When the solvent is propionic acid in combination with about 40 to about 60 volume % propylene carbonate, the concentration of ozone in the solution typically ranges from about 100 ppm to about 50 ppm, respectively.

When the solvent comprises propionic acid in combination with ethylene carbonate or with propylene carbonate, and the substrate surfaces exposed include a metal, the propionic acid typically ranges from about 40 to about 60 volume % of the solvent, with the ethylene carbonate concentration ranging from about 60 volume % to about 40 volume % of the solvent.

Pure propionic acid exhibits a vapor pressure of 390 Pa at 20° C. A propionic acid-comprising solvent for use for removal of organic material typically exhibits a vapor pressure within the range of about 100 Pa to about 600 Pa; preferably, from about 100 Pa to about 450 Pa; more preferably, from about 100 Pa to about 400 Pa.

When the solvent comprises propionic acid in combination with about 10 to about 20 volume % deionized water, the solvent typically exhibits a vapor pressure within the range of about 300 Pa to about 400 Pa (more typically, about 310 Pa to about 390 Pa). When the solvent comprises propionic acid in combination with about 40 to about 60 volume % ethylene carbonate, the solvent typically exhibits a vapor pressure within the range of about 150 Pa to about 300 Pa. When the solvent comprises propionic acid in combination with about 40 to about 60 volume % propylene carbonate, the solvent typically exhibits a vapor pressure within the range of about 150 Pa to about 300 Pa.

Propionic acid-comprising solvents typically have only a mild odor. As a result of its low vapor pressure and mild odor, propionic acid evaporates slowly, is not offensive to those working in its presence, and can be used in a more open environment with provisions for exhaust.

Propionic acid is a liquid at standard temperature (25° C.), since the melting point of propionic acid is approximately −20° C. Propionic acid has a high solubility for ozone at room temperature. The present organic material stripping and cleaning method is typically performed at a temperature in the range of 15° C. or higher. When pure propionic acid is used as the solvent, the recommended temperature range for performance of the present method is at least 15° C. and may range upward to about 50° C. When the solvent comprises propionic acid in combination with about 10 to about 20 volume % deionized water, the recommended temperature range for performance of the present method is about 15° C. to about 50° C. as well. More typically, when deionized water is present, the temperature will be in the range of about 20° C. to about 35° C.

The recommended temperature ranges are based on a combination of factors, including the time required for stripping and cleaning (removal) of the organic material and the decomposition rate of the organic material which is being stripped in the stripping solution, the volatility of the stripping solution, and the melting points of the ingredients of the stripping solution. When the solvent comprises propionic acid in combination with about 40 to about 60 volume % ethylene carbonate (which has a melting temperature of 36.4° C.), the recommended temperature range for performance of the present method is about 20° C. to about 50° C. When the solvent comprises propionic acid in combination with about 40 to about 60 volume % propylene carbonate (which has a melting temperature of −49° C.), the recommended temperature range for performance of the present method is about 20° C. to about 50° C. as well. One skilled in the art will be able to adjust the stripping temperature range for a specific application after minimal experimentation based on the present disclosure. Removal of 1 μm of DUV photoresist from a substrate surface using ozonated propionic acid has been achieved at about 25° C. in less than 30 seconds (a photoresist removal rate of about 2 μm/minute). Typically, a photoresist removal rate ranging from about 1 μm/minute to about 2 μm/minute is achieved, depending on the variable factors previously described.

Since organic compounds actually decompose (rather than just dissolve) in ozonated propionic acid, the propionic acid stripping solution can be re-used over multiple processing cycles. The number of cycles for which the stripping solution can be re-used will depend on the maximum concentration of organic material residue which is tolerable in the stripping and cleaning solution. This tolerable amount or organic residue will depend on ease of removal of the residue by a rinsing of the surface of the substrate underlying the organic material. For example, when a deionized water rinse is to be used to wash off the residual stripping and cleaning solution, rinsing of the residue without spinning of the substrate can be achieved in about 20 seconds when fresh stripping solution is used. The amount of rinse time required increases as the concentration of organic residue in the cleaning solution increases. The tolerable residue concentration can be calculated based on a cost of processing basis.

Ethylene carbonate is a colorless, odorless solid with a flashpoint of 143.7° C. and a freezing point of 36.4° C. In its pure state, ethylene carbonate is a solid at room temperature. However, ethylene carbonate is soluble in propionic acid at room temperature, and typically forms a solution at room temperature in the propionic acid solutions discussed above. Ethylene carbonate is non-reactive to ozone and non-corrosive to metals.

Like ethylene carbonate, propylene carbonate is odorless and colorless. However, propylene carbonate is a liquid at room temperature. The disadvantage of propylene carbonate is that it is less soluble in the propionic acid solutions discussed above. The addition of ethylene carbonate or propylene carbonate to a propionic acid-comprising solvent tends to further reduce the odor of the solvent, providing an advantage when a vented but open stripping process is used.

### BRIEF DESCRIPTION OF THE DRAWINGS

The teachings of the present invention can be readily understood by considering the following detailed description in conjunction with the accompanying drawings. To facilitate understanding, identical reference numerals have been used, where possible, to designate identical elements that are common to the figures.

FIG. 1 is a graph showing the concentration of dissolved ozone (in ppm) as a function of water temperature, when the deionized surface is in contact with ozone gas in oxygen at a concentration of 240 mg/L.

FIG. 2A shows a schematic of an organic material removal dispensing system of the type which can be used to process large substrate in a relatively open, vented system, where stripping solution is sprayed onto a substrate surface as the substrate moves along a conveyor.

FIG. 2B is a schematic showing a large flat panel display substrate passing through an organic material removal dispensing system, such as that shown in FIG. 2A.

FIG. 3 is a schematic of an exemplary ozonated propionic acid-comprising reagent supply system 400 which can be used to provide a stripping/cleaning reagent for removal solution of organic materials from electronic device surfaces.

FIG. 4A is a simplified schematic of a bubbler apparatus which can be used to generate vaporous propionic acid or a propionic acid-comprising solution when is then applied to a substrate surface.

FIG. 4B is a schematic showing a nozzle scanning over the surface of a substrate which is a rotating wafer, for example and not by way of limitation.

FIG. 4C is a schematic of the bubbler used in combination with a vapor distribution device designed to apply the vaporous propionic acid or propionic acid-comprising solution over a large surface of a flat glass substrate, for example.

### DETAILED DESCRIPTION OF EXEMPLARY EMBODIMENTS

As a preface to the detailed description presented below, it should be noted that, as used in this specification and the appended claims, the singular forms “a”, an and “the” include plural referents, unless the context clearly dictates otherwise. The term “about”, as used herein, refers to a value or range which may encompass plus or minus 10% of a particular cited value or range.

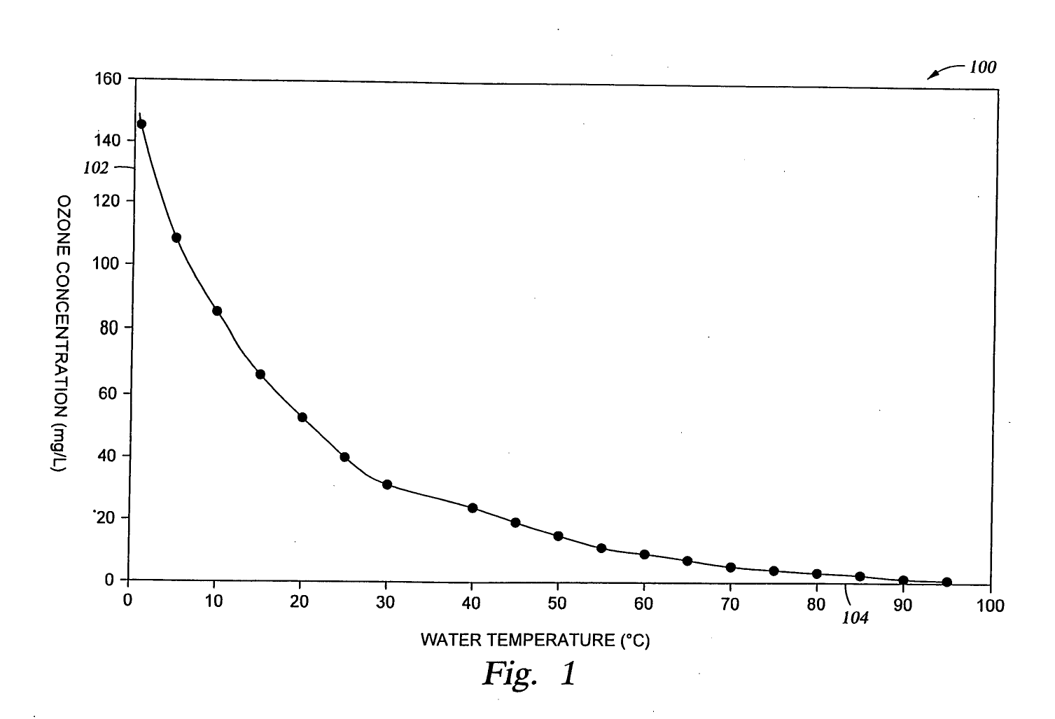

FIG. 1 is a graph 100 showing the concentration 102 of dissolved ozone (in ppm) as a function of deionized (DI) water temperature 104, when the deionized water surface is in contact with ozone gas at a concentration of 240 mg/L in air.

Ozone concentration in deionized water as a function of the deionized water temperature is also shown in Table One, below, together with the partition coefficient D (C_{liquid}/C_{gas}) of ozone in water, when the surface of the deionized water is in contact with ozone gas at a concentration of 240 mg/L in oxygen.

TABLE ONE
Ozone Concentration as a Function of Water Temperature

| Water Temperature (° C.) | O₃ Concentration (mg/L) | D (C_{liquid}/C_{gas}) |
|---|---|---|
| 1 | 145 | 0.604 |
| 5 | 109 | 0.454 |
| 10 | 85 | 0.354 |
| 15 | 66 | 0.275 |
| 20 | 52 | 0.217 |
| 25 | 40 | 0.167 |

As described in several of the publications referenced in the “Brief Description of the Background Art” section, above, the concentration of ozone in an aqueous solution can be increased by adding acetic acid to the solution. Ozone can also be dissolved in pure acetic acid. It is known that ozone dissolved in acetic acid or formic acid can be used to remove organic contamination and to strip photoresist from electronic device substrates.

Applicant has developed an improved method of removing an organic-containing material from the surface of an electronic device substrate. The improved method employs a stripping solvent (which may be a combination of ingredients) which is less corrosive to metals and/or more easily vaporized than the solvent systems previously known in the art. Applicants' method comprises exposing a surface of an electronic device substrate to a solution comprising ozone (O₃) in combination with other ingredients which are non-reactive with ozone and which exhibit a volatility which is no more than 30% higher than, and no more than 50% lower than, the volatility of propionic acid. The ozone may be dissolved in pure propionic acid, or may be dissolved in a solution containing propionic acid in combination with an ingredient selected from the group consisting of deionized water, or a carbonate having from 2 to 4 carbons.

An ozone-comprising solution of the kind described above can be used when the substrate surface includes exposed metal. The substrate surface is exposed to a solution comprising ozone (O₃) in a solvent which is a combination of ingredients, where the solvent is pure propionic acid or propionic acid in combination with group deionized water or in combination with a carbonate having from 2 to 4 carbons. The ozone-comprising solution is useful for removing organic-containing materials from the surface of substrates containing electronic devices at temperatures of about 15° C. or higher. The upper temperature limit depends on the stripping apparatus and one skilled in the art can easily determine the maximum temperature which should be used for a given apparatus.

Propionic acid is a liquid at room temperature (melting point of approximately −20° C.) and has a high solubility for ozone at room temperature. Therefore, the present organic material stripping and cleaning method can be performed at a temperature as low as about 15° C., but more typically at room temperature (25° C.) or slightly above room temperature,. The recommended temperature range for performance of the present method is about 25° C. to about 50° C. This recommended temperature range is based on a combination of factors, including the time required for stripping and cleaning (removal) of the organic material and the decomposition rate of the organic material which is being stripped in the stripping solution, the volatility of the stripping solution, and the apparatus which is used to carry out the stripping operation.

Because ozonated propionic acid, and propionic acid in combination with the various ingredients named above, is relatively non-corrosive, metal components can be used in the apparatus which makes up the delivery/application system. As discussed above, the present method can be used to strip organic materials from substrate surfaces which include exposed metals. This makes the present method particularly suitable for use in the manufacture of TFT flat panel displays, light emitting diode (LED) displays, and solar panels, by way of example and not by way of limitation.

Since organic compounds typically decompose (rather than just dissolve) in ozonated solutions containing propionic acid, a considerable amount of the decomposition products volatilized are easily removed. As a result, the stripping solution can be recycled for re-use over multiple processing cycles. The number of cycles for which the stripping solution can be re-used will depend on the maximum concentration of organic material residue which is tolerable in the stripping and cleaning solution. The maximum concentration of organic material residue which is tolerable in the stripping and cleaning solution is one which permits removal of organic residues to a tolerable level within about one minute or less, when a deionized water rinse is used to wash off the stripping solution. When a different rinse composition is used, higher organic material residues prior to rinsing may be tolerable.

Propionic acid is a preferred solvent because it is less corrosive and less volatile than acetic acid, while being easier to remove from a substrate surface and exhibiting better stability in the presence of ozone than butyric acid. Table Two, below, shows comparative information for acetic acid, propionic acid, and butyric acid.

TABLE TWO
Chemical and Physical Properties of Carboxylic Acids

| Property: | Acetic Acid | Propionic Acid | Butyric Acid |
|---|---|---|---|
| Chemical Formula | CH₃COOH | CH₃CH₂COOH | CH₃CH₂CH₂COOH |
| pKa (@ 25° C.) | 4.76 | 4.86 | 4.83 |
| Vapor Pressure | 20.9 | 5 | 0.57 |
| (mbar) | (@ 25° C.) | (@ 20° C.) | (@ 20° C.) |
| Flash Point (° C.) | 40 | 50 | 65 |
| Rate Constant (k₀) | 3 × 10⁻⁵ | 4 × 10⁻⁴ | 4 × 10⁻² |
| for Decomposition | | | |
| of Acid by | | | |
| O₃ @ pH 8 | | | |
| (M⁻¹ s⁻¹) | | | |

The corrosiveness and volatility of propionic acid can be further reduced by mixing the propionic acid with another non-corrosive organic solvent. The other non-corrosive organic solvent should be non-reactive with ozone and should exhibit a volatility which is no more than 30% higher than, and no more than 50% lower than, the volatility of propionic acid. Solvents which are non-corrosive to metals, which have little or no reactivity with ozone, which have very limited reactivity with propionic acid, which are soluble in propionic acid, and which are liquid when mixed with propionic acid are most desirable. Solvents which meet these criteria include (for example and not by way of limitation) ethylene carbonate and propylene carbonate.

Ethylene carbonate is a colorless, odorless solid with a flashpoint of 143.7° C. and a freezing point of 36.4° C. In its pure state, ethylene carbonate is a solid at room temperature. Ethylene carbonate is non-reactive to ozone, non-corrosive to metals, and is a miscible in propionic acid.

Like ethylene carbonate, propylene carbonate is odorless and colorless. Propylene carbonate is a liquid at room temperature. The disadvantage of propylene carbonate is that it is less soluble in water than ethylene carbonate, and thus more difficult to rinse off a substrate.

The solubility of ozone in ethylene carbonate or propylene carbonate is considerably less than the solubility of ozone in propionic acid (about 40 ppm ozone in ethylene carbonate, as opposed to ≧200 ppm ozone in propionic acid, at 20° C.). To provide an acceptable organic material removal rate and to maximize corrosion protection, a balance must be achieved between the concentration of propionic acid and the concentration of carbonate in the stripping solution. Typically, the short-chain carbonate comprises between about 10 and about 60 volume % of the solvent; preferably, the carbonate comprises between about 20 and about 60 volume %, of the solvent; more preferably, the carbonate comprises between about 40 and about 60 volume %, of the solvent.

As the ozone concentration in the photoresist removal solution decreases, the photoresist removal rate decreases. An acceptable ozone concentration (and photoresist removal rate) can be achieved when an ethylene carbonate or propylene carbonate concentration in the ozonated carbonate/propionic acid solution is within the range of about 10 to about 60 volume % of the photoresist removal solution. More typically, the carbonate will comprise between about 20 and about 40 volume % of the ozonated carbonate/propionic acid solution.

The present organic-containing material removal method can be performed in a simple exhausted environment, since propionic acid, alone or in combination with ethylene carbonate, propylene carbonate, and/or deionized water, is not particularly volatile or offensive in odor at temperatures of about 40° C. or lower. Due to their relatively low volatility, propionic acid-comprising solutions can be sprayed without excessive evaporation, and in most instances can be applied at room temperature, which is typically far below the flammability point of 50° C. for propionic acid.

Ideally, the ozone will decompose or oxidize the organic material completely to CO₂ or a carboxylic acid, which then is either vented through an exhaust system or is retained within the solvent. However, minimal quantities of non-oxidizable organic material components may remain after an organic material removal process. These non-oxidizable components will eventually begin to build up in the propionic acid solution. Solid contaminants which remain in the stripping solution upon recycling can be filtered out of the solution. From time to time (possibly only once a week or once a month, depending on the system), the solution may need to be refreshed to flush out any residues which are accumulating. Organic residues may be removed using a “bleed-and-feed” process.

Ozone in propionic acid is very effective at breaking the C═C double bonds in the organic material. However, C—C single bonds are more difficult to process. Ozonated deionized water is more effective than ozonated propionic acid at breaking C—C single bonds, even though the ozone concentration in ozonated deionized water is lower than the ozone concentration in ozonated propionic acid (in an open system at room temperature). For this reason, a solution containing ozone, propionic acid, and deionized water may be preferable to an ozonated propionic acid solution.

Ozonated propionic acid is very easily rinsed by deionized water, because ozonated propionic acid is lighter than (density of propionic acid=0.99 g/cm³) and completely miscible with water. Following an organic-containing material removal process, a final treatment with deionized water or ozonated deionized water can be used to rinse off the propionic acid solution and to remove any remaining organics from substrate surfaces. In one embodiment of the method, a substrate surface is first sprayed with ozonated propionic acid-comprising solution to remove organic material, followed by a second spraying with ozonated deionized water to remove any remaining organics and to rinse off the ozonated stripping solution.

In an alternative embodiment of the present method, the stripping solvent is applied to the substrate surface as a vapor (rather than as a liquid). In the case of vapor application, the use of pure propionic acid (as opposed to propionic acid in combination with other ingredients) simplifies recycling of the stripping solution. One skilled in the art will recognize that use of a combination of ingredients typically causes the vapor concentration to be different than the liquid concentration. Typically, the volatilizing temperature is within a range of about 20° C. to about 50° C. The solvent vapor is brought into contact with the substrate to be stripped of organic-containing material. The solvent vapor is condensed on the substrate surface, leaving a layer of condensed stripping solvent on the substrate surface. This condensed layer is then contacted with ozone gas. The ozone is dissolved into stripping solvent to form a condensed layer of ozonated propionic acid-comprising solvent that will remove the organic-containing material.

In the alternative, ozone gas may be used as a carrier gas to bring vaporized propionic acid-comprising stripping solvent to the workpiece surface. In this instance, the stripping solvent is more easily a combination of ingredients, as long as these ingredients can be entrained in the ozone carrier gas, to provide an ozonated stripping solution at the substrate surface.

### I. APPARATUS FOR PRACTICING THE INVENTION

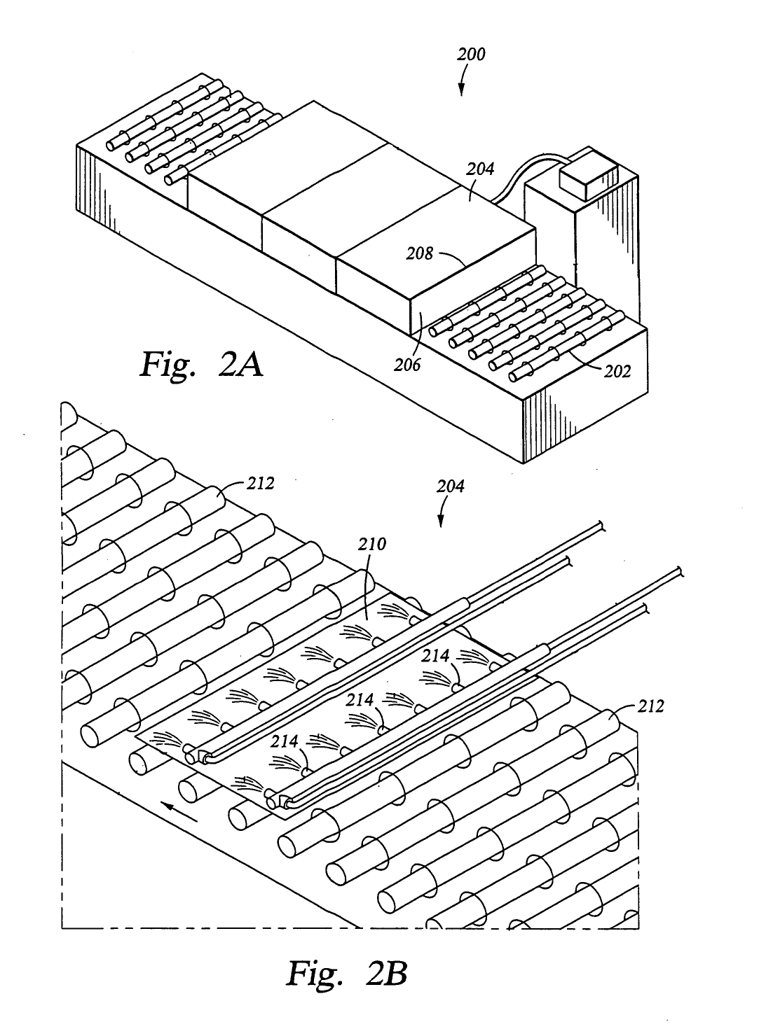

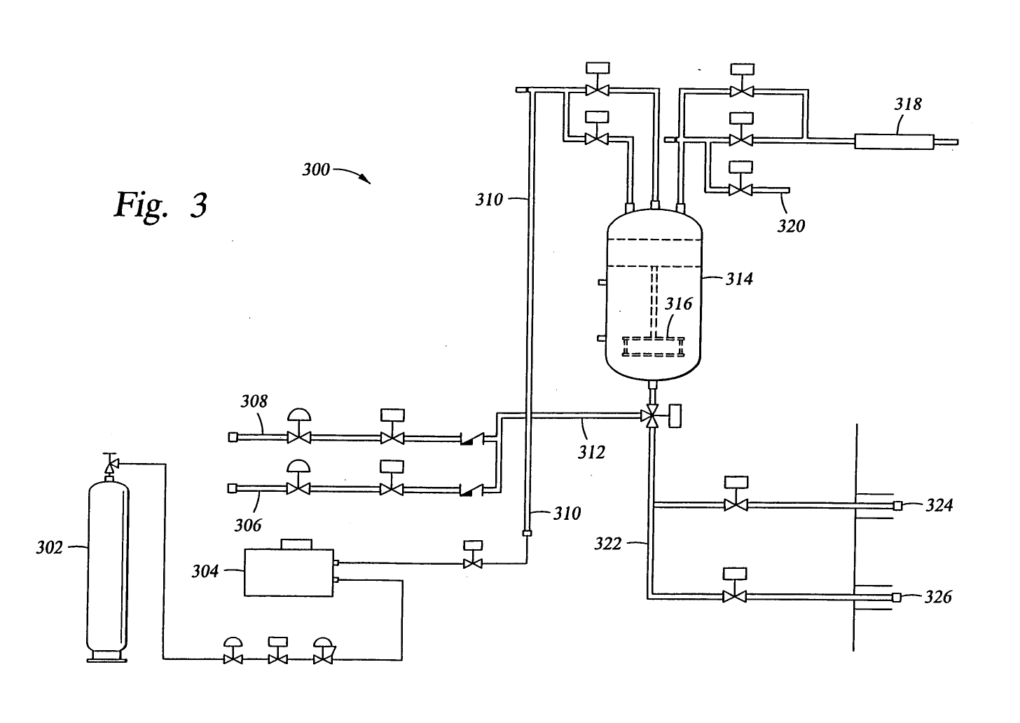

FIG. 2A shows one apparatus embodiment, in which stripping solution is applied in a spray mode on a substrate that is propagating on a conveyor belt in an open (exhausted) environment, for example and not by way of limitation. FIG. 2A shows a stripping apparatus 200 where a substrate is loaded onto an open conveyor 202, and passes into an enclosed stripping area 204 through an opening not shown in the side 206 at the leading end 208 of the enclosed stripping area. FIG. 2B shows a portion of enclosed stripping area 204, where a flat panel substrate 210 is moving across conveying rollers 212, while stripping solution is sprayed onto the surface of substrate 210 through spray nozzles 214. The spray nozzles 214 are arranged so that the entire surface of the substrate 210 will be uniformly coated with the stripping solution.

FIG. 3 is a schematic of an exemplary ozonated propionic acid-comprising solution supply system 300 which can be used to provide a stripping solution for removal of organic materials from electronic device surfaces. The stripping solution may be supplied to a spray dispenser (such as that shown in FIG. 2B), by way of example and not by way of limitation. The ozone used for ozonation of a propionic acid-comprising solvent is typically generated in an ozone generator 304 which is supplied by an oxygen source 302 (which may provide O₂ or air). Ozone from the ozone generator 304 is supplied to a solution preparation tank 314 through line 310, which feeds a sparger/mixer 316 which dispenses ozone into a liquid propionic acid-comprising solvent (not shown) which is present in solution preparation tank 314. Also included in the solution supply system 300 are (for example, and not by way of limitation) a propionic acid supply (not shown) and a deionized water supply (not shown). Propionic acid and deionized water may each be fed, from lines 306 and 308, respectively, into a common line 312, and from there to common line 322, and from line 322 into solution supply tank 314. When solution supply tank 314 is not being filled, deionized water from line 308 may be fed into common line 312, and from there to common line 322 and into line 324, which feeds a stripping apparatus (not shown). Common line 322 may also be used to drain residual ozonated propionic acid-comprising solution from solution preparation tank 314 through drain line 326. Deionized water rinse fluid may also be sent through common line 322 to drain line 326. The system may optionally include additional solvent supply apparatus (not shown) for optional solvents to be used in combination with propionic acid (such as ethylene carbonate or propylene carbonate, rather than deionized water, by way of example and not by way of limitation). Various sensors and control device may be used in the ozonated propionic acid-comprising solvent production system in a manner which would be typical in the art of flow, pressure, and temperature.

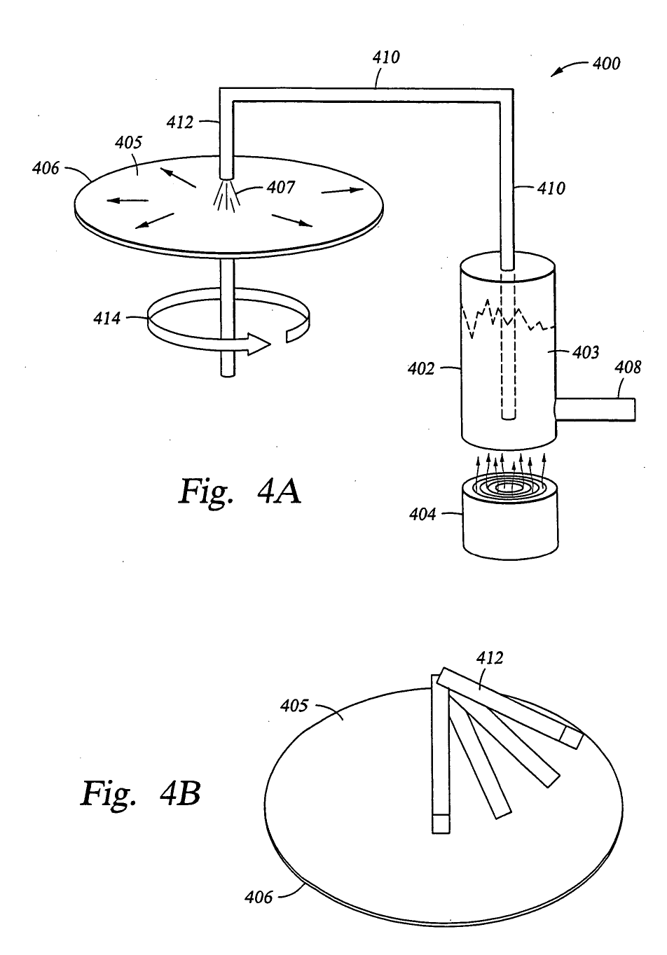

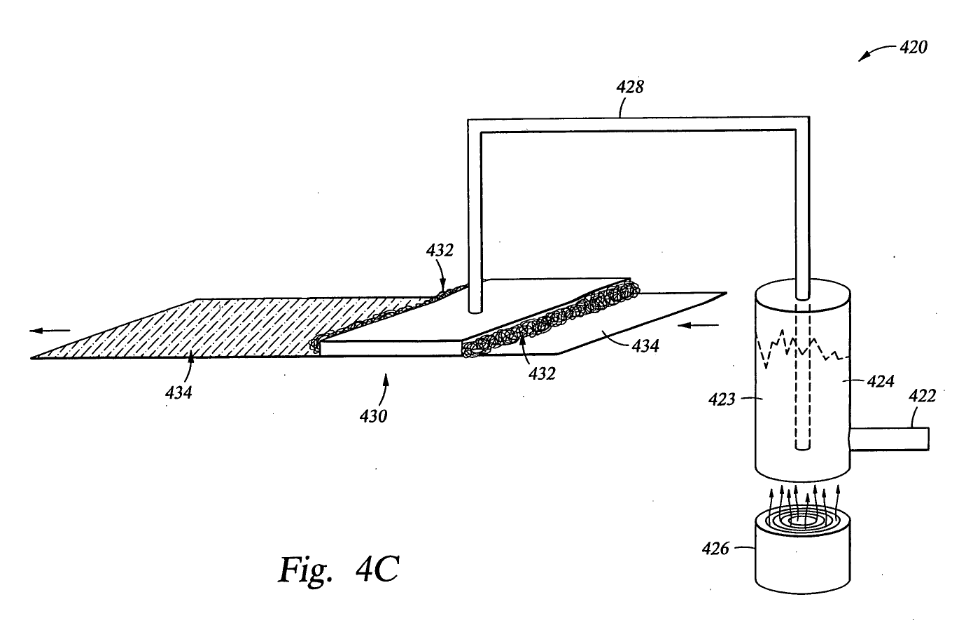

As previously discussed, the stripping solution may alternatively be applied to a substrate surface in the form of a vapor. FIG. 4A is a simplified schematic of a bubbler apparatus 400 which can be used to apply a vaporous stripping solution to a substrate 406 surface 405. For example (and not by way of limitation), propionic acid 403 in a tank 402 is heated using heater 404. Ozone gas is supplied to tank 402 through an ozone intake 408. Vaporous ozonated propionic acid is supplied from tank 402 to the surface 405 of a substrate 406 (in this example, a silicon wafer) through line 410 and nozzle 412. The temperature of the propionic acid 403 in the tank 402 is kept higher than the temperature of the wafer 406. Ozone-saturated propionic acid vapor 407 will condense on the cooler substrate surface 405. To increase mass transfer of ozone at to the substrate surface 405, fresh ozone is continuously introduced into the propionic acid solution in tank 402. The layer of stripping solution (not shown) on the substrate surface 405 is very thin, so that ozone diffuses through the layer rapidly. FIG. 4B is a close-up showing a nozzle 412 scanning over the surface 405 of substrate 406. One or more nozzles may be employed. The substrate is typically rotated as shown by arrow 414, to aid in distributing the constant feed of condensed stripping solvent (not shown) over substrate surface 405.

FIG. 4C shows a simplified schematic of a bubbler apparatus 420 where ozone is fed through ozone intake line 422 into a bubbler tank 424 containing a propionic acid-comprising solvent 423. The ozonated solvent is heated using heater 426 to produce a vapor which is fed through a line 428 into a distribution plate 430, from which stripping vapor 432 is dispensed onto a flat panel substrate 434 which is moving by distribution plate 430 on a conveyor belt (not shown).

### II. EXAMPLES

### Example One

### Removal of Photoresist from a Substrate Surface Using Ozonated Pure Propionic Acid

A layer of a deep ultra-violet (DUV) photoresist which is sensitive to 248 nm radiation (UV 6, available from Shipley, Marlborough, MA) was applied to a thickness of approximately 10,000 Å onto the surface of a single-crystal silicon wafer. The photoresist was applied using a spin-on process, then baked for 30 minutes at 95° C. Ozonated propionic acid (100% propionic acid) containing at least 300 ppm (or mg/L) of ozone was sprayed onto the surface of the photoresist-coated substrate at room temperature (25° C.), using a dispensing system such as that shown in FIG. 2B. The ozonated propionic acid was allowed to react with the photoresist for a period of 30, 60, or 120 seconds, then rinsed off the substrate surface by spraying with deionized water for a period of 10 to 20 seconds.

Table Three, below, shows the amount of photoresist which was removed from each substrate. Within the accuracy of our ability to measure, essentially all of the photoresist was removed from the silicon wafer surface in each case.

TABLE THREE
Photoresist Removal Using Ozonated Propionic Acid

| Sample # | Treatment Time (sec) | Photoresist Removed (Å) |
|---|---|---|
| 1 | 30 | 10,000 |
| 2 | 30 | 9947 |
| 3 | 60 | 9968 |
| 4 | 60 | 9942 |
| 5 | 120 | 10,000 |
| 6 | 120 | 9953 |

The data in Table Three show that 10,000 Å of photoresist can be removed from the surface of a single-crystal silicon substrate in 30 seconds (or less).

### Example Two

### Corrosivity of Ozonated Propionic Acid on Aluminum

A layer of aluminum was deposited to a thickness of approximately 10,000 Å onto the surface of a single-crystal silicon wafer using a physical vapor deposition (PVD) process of the kind known in the art. To test the corrosivity of ozonated propionic acid on aluminum, ozonated propionic acid (100% propionic acid) containing at least 300 ppm (or mg/L) of ozone was sprayed onto the surface of the aluminum-coated substrate at room temperature (25° C.), using a dispensing system such as that shown in FIG. 2B. The ozonated propionic acid was allowed to react with the aluminum for a period of 30, 60, or 120 seconds, then rinsed off the substrate surface by spraying with deionized water for a period of 10 to 20 seconds.

Table Four, below, shows the thickness of the aluminum layer before and after treatment.

TABLE FOUR
Corrosivity of Ozonated Propionic Acid Stripping Solution
on Aluminum

| | | Pre-Treatment | Post- | |
|---|---|---|---|---|
| | Treatment | Al Thickness | Treatment Al | Al Removed |
| Sample # | Time (sec) | (Å) | Thickness (Å) | (Å) |
| 7 | 30 | 9583 | 9584 | −0.6 |
| 8 | 60 | 9563 | 9596 | −33 |
| 9 | 60 | 9609 | 9624 | −15 |
| 10 | 120 | 9600 | 9616 | −16 |
| 11 | 120 | 9612 | 9644 | −32 |

The data in Table Four indicate that, within the accuracy of our ability to measure, the aluminum is not removed by ozonated propionic acid. There appears to be a slight increase in the thickness of the aluminum layer. The increase in thickness of the aluminum layer may be due to the formation of Al₂O₃ on the surface of the aluminum layer due to exposure to O₃. Treatment of the aluminum surface to remove oxide may be carried out if necessary to permit device function in the end use application.

### Example Three

### Corrosivity of Ozonated Propionic Acid on Titanium Nitride

A layer of titanium nitride was deposited to a thickness of 450 Å onto the surface of a single-crystal silicon wafer using a physical vapor deposition (PVD) process. In order to test the corrosivity of ozonated propionic acid on titanium nitride, ozonated propionic acid (100% propionic acid) containing at least 300 ppm (or mg/L) of ozone was sprayed onto the surface of the TiN-coated substrate at room temperature (25° C.), using a dispensing system such as that shown in FIG. 2B. The ozonated propionic acid was allowed to react with the titanium nitride surface for a period of 30, 60, or 120 seconds, then rinsed off the substrate surface by spraying with deionized water for a period of 10 to 20 seconds.

Table Five, below, shows the thickness of the titanium nitride layer before and after treatment.

TABLE FIVE
Corrosivity of Ozonated Propionic Acid Cleaning Solution
on Titanium Nitride

| | | Pre-Treatment | Post- | |
|---|---|---|---|---|
| | Treatment | TiN Thickness | Treatment TiN | TiN Removed |
| Sample # | Time (sec) | (Å) | Thickness (Å) | (Å) |
| 12 | 30 | 450 | 411 | 38 |
| 13 | 30 | 450 | 422 | 28 |
| 14 | 60 | 450 | 418 | 32 |
| 15 | 60 | 450 | 424 | 26 |
| 16 | 120 | 450 | 422 | 28 |
| 17 | 120 | 450 | 425 | 25 |

Within the accuracy of our ability to measure, the data in Table Five indicate that the thickness of the TiN layer decreased only slightly upon exposure to ozonated propionic acid. The measured loss in TiN thickness was independent of exposure time (which ranged from 30 to 120 seconds) and suggests the growth of a very thin surface oxide layer.

While the invention has been described in detail above with reference to several embodiments, various modifications within the scope and spirit of the invention will be apparent to those of working skill in this technological field. Accordingly, the scope of the invention should be measured by the appended claims.

We claim:

1. A method of removing an organic-containing material from a surface of an electronic device substrate, wherein said method comprises exposing said surface to a solution comprising ozone (O₃) in a solvent, wherein the concentration of ozone in the solution is about 45 ppm or greater, and wherein said solvent is non-reactive with ozone and exhibits a volatility which is no more than 30% higher than, and no more than 50% lower than, the volatility of propionic acid.

2. A method in accordance with claim 1, wherein said solvent is pure propionic acid.

3. A method in accordance with claim 1, wherein said solvent comprises propionic acid in combination with deionized water or a carbonate having from 2 to 4 carbons.

4. A method in accordance with claim 1, wherein said solvent comprises propionic acid in combination with a carbonate having from 2 to 4 carbons.

5. A method of removing an organic-containing material from a surface of an electronic device substrate surface, where the surface includes exposed metal, wherein said method comprises exposing said metal-containing surface to a solution comprising ozone (O₃) in a solvent, where the concentration of ozone ranges from about 4 5 ppm to about 600 ppm, and wherein said solvent is propionic acid in combination with a carbonate having from 2 to 4 carbons.

6. A method in accordance with claim 5, wherein said solvent is pure propionic acid.

7. A method in accordance with claim 6, wherein said solvent comprises propionic acid in combination with a carbonate having from 2 to 4 carbons, and wherein said carbonate comprises between about 10 and about 60 volume % of said solvent.

8. A method in accordance with claim 7, wherein said carbonate comprises between about 20 and about 60 volume % of said solvent.

9. A method in accordance with claim 8, wherein said carbonate comprises between about 40 and about 60 volume % of said solvent.

10. A method in accordance with claim 7, wherein said carbonate is ethylene carbonate.

11. A method in accordance with claim 7, wherein said carbonate is propylene carbonate.

12. A method in accordance with claim 5, wherein said solution has an ozone concentration within the range of about 50 ppm to about 300 ppm.

13. A method in accordance with claim 5, wherein said solvent exhibits a vapor pressure within the range of about 100 Pa to about 600 Pa.

14. A method in accordance with claim 5, wherein said method is performed at a temperature within the range of about 15° C. to about 50° C.

15. A method in accordance with claim 14, wherein said method is performed at a temperature within the range of about 20° C. to about 35° C.

16. A method in accordance with claim 5, wherein said exposed metal includes copper or molybdenum.

17. A method in accordance with claim 5, wherein said method is used in the manufacture of an electronic device selected from the group consisting of a flat panel display, a solar cell array, a structure containing a light-emitting diode, and a solid state device-containing semiconductor substrate

18. A method in accordance with claim 5, wherein said method is performed in an open, exhausted environment.

19. A method in accordance with claim 5, wherein said solvent is continuously recycled for re-use.

20. A method in accordance with claim 5, wherein, following performance of said method, said substrate surface is rinsed using a solution of ozone in deionized water, wherein the concentration of ozone ranges from about 50 ppm to about 600 ppm.

21. A method in accordance with claim 5, wherein said organic-containing material is a photoresist, and wherein said method provides a photoresist removal rate of at least 100 Å/second.

22. A method in accordance with claim 5, wherein said solution is sprayed in liquid state onto said electronic device substrate surface.

23. A method in accordance with claim 5, wherein said solution is applied to said electronic device substrate surface in a vaporous state.

24. A method of removing an organic-containing material from a surface of an electronic device substrate surface, where the surface includes exposed metal, wherein said method comprises exposing said metal-containing surface to a solution comprising ozone (O₃) in a solvent, wherein a concentration of ozone ranges from about 50 ppm to about 600 ppm, and wherein said solvent is propionic acid in combination with at least one other ingredient selected from the group consisting of deionized water, a carbonate having from 2 to 4 carbons, and combinations thereof.

25. A method in accordance with claim 24, wherein said solvent comprises propionic acid in combination with deionized water, wherein said deionized water comprises between about 10 and about 20 volume % of said solvent.

26. A method in accordance with claim 24, wherein said solution has an ozone concentration within the range of about 50 ppm to about 300 ppm.

27. A method in accordance with claim 24, wherein said solvent exhibits a vapor pressure within the range of about 300 Pa to about 400 Pa.

28. A method in accordance with claim 24, wherein said method is performed at a temperature within the range of about 15° C. to about 50° C.

29. A method in accordance with claim 28, wherein said method is performed at a temperature within the range of about 20° C. to about 35° C.

30. A method in accordance with claim 24, wherein said exposed metal includes copper or molybdenum.

31. A method in accordance with claim 24, wherein said method is used in the manufacture of an electronic device selected from the group consisting of a flat panel display, a solar cell array, a structure containing a light-emitting diode, and a solid state device-containing semiconductor substrate.

32. A method in accordance with claim 24, wherein said method is performed in an open, exhausted environment.

33. A method in accordance with claim 24, wherein said solvent is recycled for re-use.

34. A method in accordance with claim 24, wherein, following performance of said method, said substrate surface is rinsed using a solution of ozone in deionized water, where the concentration of ozone ranges from about 50 ppm to about 600 ppm.

35. A method in accordance with claim 24, wherein said organic-containing material is a photoresist, and wherein said method provides a photoresist removal rate of at least 0.5 μm/min.

36. A method in accordance with claim 24, wherein said solution is sprayed in liquid state onto said electronic device substrate surface.
